(19) United States
(12) Patent Application Publication
(10) Pub. No.: US 2026/0301849 A1
(43) Pub. Date: Oct. 1, 2026

(54) Memory with Double Redundancy

(71) Applicant: QUALCOMM Incorporated, San Diego, CA (US)

(72) Inventors: Kiran DHAMANE, Sangli (IN); Debarghya DUTTA, KOLKATA (IN); Rahul SAHU, Bangalore (IN); Anoop KUMAR, Bhadohi (IN)

(21) Appl. No.: 19/091,627

(22) Filed: Mar. 26, 2025

(51) Int. Cl. G11C 29/00

(52) U.S. Cl. CPC G11C 29/76; G11C 29/789

(57) ABSTRACT

A memory is provided with a bank including a plurality of global input/output (GIO) columns and a corresponding plurality of GIO circuits. Each GIO circuit includes a switch matrix. In a no-shift region, the switch matrix couples the GIO circuit to a core in the corresponding GIO column. In a one-shift region, the switch matrix couples the GIOO circuit to a core in a subsequent GIO column. In a two-shift region, the switch matrix couples the GIO circuit to a core in a next-to-subsequent GIO column.

### TECHNICAL FIELD

This application relates to memories, and more particularly to a memory bank that may replace a pair of defective columns with two redundant columns.

### BACKGROUND

A static random-access memory (SRAM) includes an array of bitcells arranged into rows and columns. To enhance performance such as by lowering the bit line capacitance, the array of bitcells is typically subdivided into banks. Without redundancy, a single error to a bank may render the entire bank inoperative. It is thus conventional for each bank to have a redundant column so that the bank may replace a defective column with the redundant column.

There are two main ways to implement column redundancy: Input/Output (I/O) shifting and sense amplifier shifting. I/O shifting is simpler to implement but requires more semiconductor die space as compared to sense amplifier shifting. In both types of column redundancy, each bank may replace a defective column through the use of a redundant column. A bank may thus replace a single defective column using the redundant column. But defects to two columns in a single bank may render the bank inoperative.

### SUMMARY

In accordance with an aspect of the disclosure, a memory is provided that includes: a first global input/output column of bitcells; a second global input/output column of bitcells; a third global input/output column of bitcells, wherein the first global input/output column, the second global input/output column, and the third global input/output column are arranged in a consecutive order within a first bank; a first data output latch; and a switch matrix including a first switch connected between an output terminal of the first global input/output column and an input terminal of the first data output latch, a second switch connected between an output terminal of the second global input/output column and the input terminal of the first data output latch, and a third switch coupled between an output terminal of the third global input/output column and the input terminal of the first data output latch

In accordance with another aspect of the disclosure, a memory is provided that includes: a first global input/output column of bitcells; a second global input/output column of bitcells; a third global input/output column of bitcells, wherein the first global input/output column, the second global input/output column, and the third global input/output column are arranged in a consecutive order; a first data input latch; and a first switch matrix having a first switch connected between an output terminal of the first data input latch and an input terminal of the first global input/output column, a second switch connected between the output terminal of the first data input latch and an input terminal of the second global input/output column, and a third switch coupled between the output terminal of the first data input latch and an input terminal of the third global input/output column.

In accordance with yet another aspect of the disclosure, a method of memory redundancy is provided that includes: closing a single first switch to connect a first latch to a first global input/output column in a plurality of global input/output columns responsive to a subset of the plurality of global input/output columns that extends from an initial global input/output column to the first global input/output column having no defects; closing a single second switch to connect the first latch to a second global input/output column in the plurality of global input/output columns responsive to the first global input/output column including a first defective column, wherein the second global input/output column is adjacent to the first global input/output column; and closing a single third switch to connect the first latch to a third global input/output column in the plurality of global input/output columns responsive to the second global input/output column including a second defective column, wherein the third global input/output column is adjacent to the second global input/output column.

These and additional advantages may be better appreciated through the following detailed description.

### BRIEF DESCRIPTION OF THE DRAWINGS

FIG. 1 illustrates a memory having a double redundancy shift in accordance with an aspect of the disclosure.

FIG. 2 illustrates a portion of the memory of FIG. 1 including the local data paths and the I/O circuits in accordance with an aspect of the disclosure.

FIG. 3 illustrates a portion of a read path for a bank with double redundancy in accordance with an aspect of the disclosure.

FIG. 4 illustrates a portion of a write path for a bank with double redundancy in accordance with an aspect of the disclosure.

FIG. 5 is a circuit diagram of a decoder for a bank with double redundancy in accordance with an aspect of the disclosure.

FIG. 6 is a flowchart of a double redundancy shift method for a memory bank in accordance with an aspect of the disclosure.

FIG. 7 illustrates some example electronic systems incorporating a double redundancy shift memory in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

The bitcells in an SRAM are arranged into banks with each bank having its own rows and columns. A corresponding pair of bit lines traverses each column whereas a corresponding word line traverses each row of bitcells. Adjacent ones of the bit lines are separated by a bit line pitch. As the transistor size has decreased, the bit line pitch has decreased accordingly. This reduced bit line pitch typically prevents the memory designer from implementing a sense amplifier within the bit line pitch for a column to sense the bit line pair during a read operation. The columns are thus typically arranged into columns with the columns corresponding to a global input/output (GIO) signal being selected by a corresponding column multiplexer during a read or write operation. As used herein, the term “GIO column” is thus understood to refer to the columns that are multiplexed within a single bank for a single GIO. In contrast, the term “column” without any further limitation is defined herein to refer to an individual column within a GIO column.

A GIO signal is typically shared between banks such that a global data output latch may latch a data output signal from a GIO column in a first bank or from a corresponding GIO column in a second bank. Similarly, a global data input latch latches a data input signal that is then written to a GIO column in the first bank or to a corresponding GIO column in the second bank. It may thus be appreciated why a GIO is designated as “global” in that it is shared between banks and within a bank it is shared by the columns within a GIO column.

The column multiplexing for a GIO depends upon the implementation. In a “MUX2” implementation, each GIO column includes two columns. Similarly, in a “MUX4” implementation, each GIO column includes four columns. The number of redundant columns for a bank depends upon how many defective columns can be replaced and whether I/O shifting or sense amplifier shifting is used. For example, the columns in a MUX2 implementation may be denoted as being either odd or even. Each GIO column thus includes one odd column and one even column. Should sense amplifier shifting be used to implement redundancy, a single redundant column may be used in a replacement of either a defective even column or a defective odd column. In contrast, two redundant columns are used for a replacement of a defective MUX2 GIO column. It may thus be appreciated that sense amplifier shifting typically has increased density (requires less semiconductor die space to implement) as compared to IO shifting column redundancy. But the use of sense amplifier shifting generally comes at the cost of increased complexity and switching delays.

Even if IO shifting is used, the complexity and switching delays may increase if more than one defective column may be replaced in each bank. An advantageous IO shifting for memory with double column redundancy is disclosed herein that offers reduced complexity and reduced switching delays. Before this advantageous memory is discussed in more detail, some terminology and memory concepts will first be reviewed. In an SRAM bank, each bitcell stores a bit signal and a complement of the bit signal. To access these complementary signals, a bitcell couples to a pair of bit lines. An SRAM bank includes a plurality of such bit line pairs, each bit line pair coupling to a single column of bitcells arranged in rows in the single column according to corresponding word lines. During a write operation, an input latch in a global input/output circuit (which is also denoted as a GIO circuit herein) couples to a selected bitcell through the corresponding bit line pair. Similarly, during a read operation, an output latch in the GIO circuit couples to a selected bitcell through the corresponding bit line pair.

This coupling between a bit line pair (and the corresponding bitcell) and an input/output circuit may be multiplexed as discussed earlier. For example, in a “MUX2” implementation, the bit line pairs may be organized into odd and even pairs within a GIO column. Depending upon the multiplexing, a GIO circuit may then couple to a selected bit line pair from a corresponding odd and even pair of bit lines. In a write operation, the GIO circuit may then couple through a write driver and a write column multiplexer to the selected bit line pair. Similarly, during a read operation, the GIO circuit may couple through a read column multiplexer and a sense amplifier to the selected bit line pair. Other types of multiplexing of bit line pairs may be used such as in a “MUX4” implementation in which each input/output circuit may couple to one of four multiplexed columns.

With regard to the column multiplexing, a combination of a write driver, a write column multiplexer, a read column multiplexer, and a sense amplifier may be denoted herein as a “local data path.” The bit lines and bitcells within a GIO column are also denoted herein as a “core.” The following discussion will be directed to implementations in which each I/O circuit is a global I/O circuit, but it will be appreciated that the I/O shifting disclosed herein is applicable to implementations in which the I/O circuits are local I/O circuits. The term “global” I/O circuit is used in that a global I/O circuit may be shared between two banks whereas a local I/O circuit pertains to only one bank. In the following discussion, each global I/O circuit will also be referred to as simply an “I/O circuit” for brevity.

To address the possibility of two defective GIO columns in a single bank, a memory is disclosed herein with double column redundancy. If there are no defective GIO columns in the memory bank, a switch matrix in each GIO circuit is configured to couple a latch in the GIO circuit to a corresponding default GIO column. With regard to what is meant by a “default” GIO column, the GIO columns may be deemed to be indexed such that consecutive GIO columns differ by one with respect to their indices. The GIO circuits have the same indexing. For example, the GIO columns may be deemed to be indexed from one to N, where N is a plural positive integer. The GIO circuits may then have the same indexing. The default GIO column for a given GIO circuit is thus the GIO column having the same index.

During a read operation in a bank without any defective columns, a retrieved data bit from the default GIO column couples through the switch matrix to an output latch in the GIO circuit. Similarly, an input latch in the GIO circuit provides a data bit to be written to the default GIO column during a write operation. Should the memory bank include a single defective column, one or more of the GIO circuits may instead each couple through its respective switch matrix to a neighboring GIO column. For example, suppose that there are N GIO columns in a bank, arranged from an (N−1)th GIO column to a zeroth GIO column, where N is a positive plural integer. There would then be N GIO circuits: an (N−1)th GIO circuit corresponding to the (N−1)th GIO column, an (N−2)th GIO circuit corresponding to the (N−2)th GIO column and so on to a zeroth GIO circuit corresponding to the zeroth GIO column. Without any errors, each GIO circuit couples through its switch matrix to the corresponding GIO column. But suppose that an ith GIO column is a first defective GIO column in the bank, where i is an integer that is less than N. From the Nth GIO column to the (i+1)th GIO column, each GIO circuit continues to couple to its default GIO column as discussed previously. From the ith GIO column to the zeroth GIO column, each GIO circuit instead couples to a neighboring or adjacent GIO column to the default GIO column. For example, the ith GIO circuit couples to the (i−1)th GIO column, the (i−1)th GIO circuit couples to the (i−2)th GIO column, and so on such that the zeroth GIO circuit couples to a first redundant GIO column. In the case of such a single defective GIO column, the array of GIO columns may thus be divided into a no-shift region in which each GIO circuit couples to the default GIO column and into a one-shift region in which each GIO circuit couples to a consecutive or neighboring GIO column to the default GIO column.

Should instead there be two defective GIO columns in a single bank, the plurality of GIO columns may instead be divided into a no-shift region, a one-shift region, and a two-shift region. The no-shift region and the one-shift region are as discussed earlier and are demarcated by an initial defective GIO column. A preceding (j−1)th GIO column to a second defective (jth) GIO column is an initial GIO column in the two-shift region, where j is an integer less than I and greater than or equal to zero. Each GIO circuit in the two-shift region couples to a next-to-neighboring GIO column to the GIO circuit's default GIO column. For example, suppose that the initial defective GIO column is the ith GIO column as discussed previously. The second defective GIO column may then be designated as a jth GIO column, where j is an integer that less than i and greater than or equal to zero. A (j+1)th GIO column would then separate the one-shift region from the two-shift region. In such a case, the (j+1)th GIO circuit would couple to the (j−1)th GIO column, the jth GIO circuit would couple to the (j−2)th GIO column, and so on such that a first GIO circuit would couple to the first redundant GIO column and a zeroth GIO circuit would couple to the second redundant GIO column.

In a given bank, the entire plurality of GIO columns forms a no-shift region if there are no defective GIO columns. In such a case, there is no one-shift region nor is there a two-shift region. If there is only one defective GIO column, the plurality of GIO columns is divided into a no-shift region and a one-shift region, there being no two-shift region. If there are two (non-consecutive) defective GIO columns, the plurality of GIO columns is divided into a no-shift region, a one-shift region, and a two-shift region. A memory with two consecutive defective GIO columns may be divided into a no-shift region and a two-shift region (there being no one-shift region).

To identify the defective GIO column(s), the memory may be tested such as at manufacture. The memory may be an embedded memory in a system such as a system on a chip (SoC). The address of the defective GIO columns may then be stored in a read-only memory in the SoC such as an array of fuses. During normal operation of the SoC, a GIO column in the plurality of GIO columns in the memory is addressed for a read or write operation. There are then three possibilities: 1) the addressed GIIO column is in a no-shift region, 2) the addressed GIO column is in a one-shift region, and 3) the addressed GIO column is in a two-shift region. To determine which of these three possibilities exists for the addressed GIO column, each I/O circuit includes a redundancy decoder. For brevity, each redundancy decoder will simply be denoted as a decoder in the following discussion.

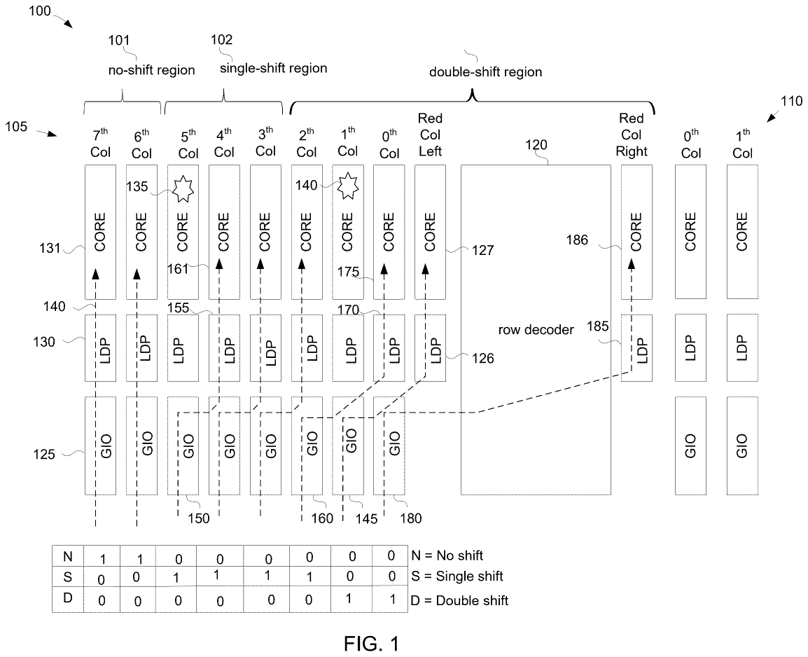

This double-column-redundancy IO shifting may be better appreciated through a consideration of an example memory 100 shown in FIG. 1 that includes a first bank 105 and a second bank 110 separated by a row decoder 120. Each bank includes a plurality of eight GIO columns that each includes a bitcell core and a local data path. The GIO columns are arranged from a zeroth column to a seventh column (for illustration clarity, bank 110 is shown just with two GIO columns). Since there are eight GIO columns in bank 105, there are eight corresponding GIO circuits arranged from a seventh GIO circuit 125 to a zeroth GIO circuit 180. In a no-shift state, these GIO circuits couple on a one-to-one basis with a default one of the eight GIO columns in the bank 105. For example, the seventh I/O circuit 125 couples to the seventh GIO column whereas the zeroth I/O circuit 180 would couple to the zeroth GIO column. Each GIO circuit couples to a GIO column through the GIO column's local data path (LDP). For example, the seventh I/O circuit 125 may couple through a LDP 130 to a core 131 for the seventh GIO column. Each GIO column's local data path may include write multiplexers and read multiplexers (not illustrated) as will be explained further herein.

In bank 105, the 5^{th} GIO column has a first defect 135. The 5^{th} GIO column is thus the first defective GIO column in bank 105. The seventh and sixth GIO columns are therefore in a no-shift region 101. As will be explained further herein, each GIO circuit from a 5^{th} GIO circuit 150 through the zeroth GIO circuit 180 will thus be in either a one-shift region 102 or a two-shift region 103. Should the 5th GIO column be the only defective GIO column in bank 105, the one-shift region 102 would extend from the 5^{th} GIO column to the zeroth GIO column. But bank 105 has a second defect 140 in the first GIO column. The first GIO column is thus a second defective GIO column in bank 105. One-shift region 102 thus ends at the third GIO column. Two-shift region 103 extends from the second GIO column to the zeroth GIO column.

In no-shift region 101, each GIO circuit couples to the local data path and core for the GIO circuit's default GIO column. For example, the seventh GIO circuit 125 thus couples through local data path 130 to a core 131 for the 7^{th} GIO column. The coupling for each GIO circuit is represented by an arrow 140. As implied by the designation of “one-shift,” each GIO circuit in one-shift region 102 does not couple to its default GIO column but instead couples through the local data path for the subsequent GIO column to its default GIO column's core. For example, the 5^{th} GIO circuit 150 couples through a local data path 155 to a core 161 for the 4^{th} GIO column. Similarly, each GIO circuit in two-shift region 103 couples through the local data path for the next-to-neighboring GIO column to the GIO circuit's default GIO column. For example, a second GIO circuit 160 in two-shift region 103 couples through a local data path 170 to a core 175 for the 0^{th} GIO column.

A first redundant GIO column (Red Col Left) is located to the left of the row decoder 120 whereas a second redundant GIO column is located to the right of the row decoder 120. The double column redundancy disclosed herein may thus also be designated as a left-right (LR) column redundancy in that it may use the left and right redundant GIO columns. Since bank 105 has two errors, both the right and the left redundant GIO columns are used for its IO shifting. In the two-shift region 103, a first GIO circuit 145 couples through a first redundant local data path 126 to a core 127 for the left redundant GIO column. Similarly, the zeroth GIO circuit 180 couples through a second redundant local data path 185 to a core 186 for the right redundant GIO column.

To enable the no-shift, single-shift, and double shift behavior, each GIO circuit includes a switch matrix (not illustrated in FIG. 1) that is controlled by a plurality of redundancy shift signals. The switch matrix typically includes two levels of switches such that data input signals from a GIO circuit couple through two switches to a local data path and a GIO column for a write operation. Similarly, data output signals from a GIO column couple through two switches in passing from the corresponding local data path to a GIO circuit. As will be explained further herein, memory 100 has an advantageous double column redundancy such that each switch matrix includes just a single level of switches. Given this single level, a data output signal to a GIO circuit connects through just one switch in the GIO circuit's switch matrix during a read operation. Similarly, a data input signals from a GIO circuit passes through just one switch in the GIO circuit's switch matrix during a write operation.

As part of this advantageous single-level switch matrix operation, each GIO circuit's redundancy decoder may generate a no-shift (N) signal, a single-shift(S) signal, and a double-shift (D) signal. These signals are mutually exclusive such that only one of them may be asserted during a read or write operation. As used herein, a binary signal is deemed to be “asserted” when the binary signal is logically true, regardless of whether the true state is represented using an active-high or active-low convention. The N, S, and D signals are also shown in FIG. 1 for the bank 105. In the no-shift region 101, only the corresponding N signal is asserted for each GIO circuit whereas the S and D signals are both de-asserted. Similarly, only the corresponding S signal is asserted for each GIO circuit in the single-shift region 102. Finally, only the corresponding D signal is asserted for each GIO circuit in the double-shift region.

The arrangement of the GIO circuits from the 7^{th} I/O circuit 125 to the zeroth I/O circuit 180 provides a basis for what is denoted herein as a “preceding” GIO circuit and as a “subsequent” GIO circuit. Excluding the 7th GIO circuit 125, each GIO circuit has a preceding GIO circuit in the GIO circuit arrangement. For example, the second GIO circuit 160 is the preceding GIO circuit to the first GIO circuit 145. More generally, an ith GIO circuit is the preceding GIO circuit to an (i−1)th GIO circuit, where i is a positive integer. Excluding the zeroth GIO circuit 180, each GIO circuit has a subsequent GIO circuit in the GIO circuit arrangement. For example, the first GIO circuit 145 is the subsequent GIO circuit to the second GIO circuit 160. More generally, an (i−1)th GIO circuit is the subsequent GIO circuit to an ith GIO circuit, where i is again a positive integer. Note that this arrangement is arbitrary and may be reversed in alternative implementations in which the two redundant GIO columns would be adjacent the last GIO column as opposed to being adjacent to the zeroth GIO column.

This definition of a preceding GIO circuit and a subsequent GIO circuit in turn provides a basis for a definition of what is denoted herein as “feedback” signals and “feedforward” signals. A feedback signal propagates from a given GIO circuit to the preceding GIO circuit. Conversely, a feedforward signal propagates from a given GIO circuit to the subsequent GIO circuit.

Each of the GIO columns except the right redundant GIO column may be deemed to have a subsequent GIO column. For example, the subsequent GIO column to the left redundant GIO column is the right redundant GIO column. Similarly, each GIO column except the redundant GIO columns may be deemed to have a next-to-subsequent GIO column. For example, the next-to-subsequent GIO column for the zeroth GIO column is the right redundant GIO column. In the same fashion, the next-to-subsequent GIO column for the first GIO column is the left redundant column, the next-to-subsequent GIO column for the second GIO column is the zeroth GIO column, and so on.

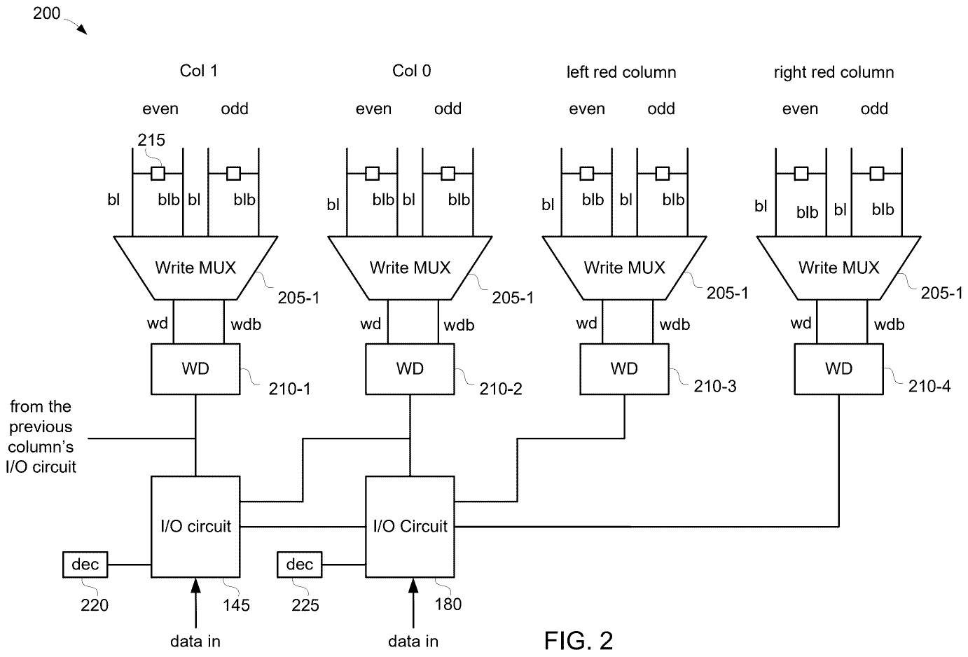

As noted earlier, the term “GIO column” encompasses the local data path and the associated core of multiplexed bit line pair(s) and bitcells. For example, in a “MUX 2” implementation of memory array 100, each of the GIO columns includes both an even bit line pair and an odd bit line pair. Depending upon the column addressing, each GIO circuit then couples to either an even bit line pair or an odd bit line pair in such an implementation. More generally, each GIO column may include a plurality of multiplexed bit line pairs that depends upon the dimension or magnitude of the column multiplexing. A portion 200 of a MUX2 implementation of bank 105 is shown in FIG. 2. For illustration clarity, portion 200 only includes the 1^{st} GIO column (Col 1), the zeroth GIO column (Col 0), the left redundant GIO column (left red column) and the right redundant GIO column (right red column). The GIO circuit 145 is the default GIO circuit for the first GIO column. Similarly, the zeroth GIO circuit 180 is the default GIO circuit for the zeroth GIO column. Each of the first GIO column, the zeroth GIO column, the left redundant GIO column, and the right redundant GIO column includes both an even bit line pair and an odd bit line pair. Each even bit line pair and odd bit line pair is formed by a bit line bl and a complement bit line blb. Each bit line pair couples to a plurality of bitcells arranged into rows. For illustration clarity, only one bitcell is shown for each bit line pair. For example, the even bit line pair in the first GIO column couples to a bitcell 215. The bit line pairs and bitcells for each GIO column forms the GIO column's core. For illustration clarity, the local data path in each GIO column is represented only by a write multiplexer and a write driver (WD) but it will be appreciated that a corresponding read multiplexer and sense amplifier would also be included in such a MUX2 implementation. The first GIO column thus includes a write driver 210-1 and a write multiplexer 205-1, the zeroth GIO column includes a write driver 210-2 and a write multiplexer 205-2, the left redundant GIO column includes a write driver 210-3 and a write multiplexer 205-3, and the second redundant GIO column includes a write driver 210-4 and a write multiplexer 205-4. Depending upon a data input signal during a write operation, each write driver controls the binary state (true or false) of a write driver (wd) signal and a complement write driver (wdb) signal to the corresponding write multiplexer. Depending upon whether the even or odd bit line pair is selected, each write multiplexer then drives the appropriate bit line pair accordingly.

If there are no errors in such an implementation, then the first GIO column and the second GIO column would be in a no-shift region. In that case, I/O circuit 145 responds to its data in signal during a write operation to connect to write driver 210-1 in the first GIO column accordingly. Similarly, the zeroth I/O circuit 180 would respond to its data in signal during a write operation to connect to write driver 210-2 in the zeroth GIO column in such a no-shift condition. Neither the first redundant GIO column nor the second redundant GIO column is used in that case.

Should the first and zeroth GIO columns be included in a one-shift region, the first I/O circuit 145 couples to write driver 210-2 in the zeroth GIO column during a write operation addressing the first GIO column. Similarly, the zeroth I/O circuit 180 couples to write driver 210-3 in the first redundant GIO column in such a one-shift condition during a write operation to the zeroth GIO column. Each GIO circuit includes a decoder that controls whether the GIO circuit shifts or not. Each decoder is shown separately in FIG. 2 from its GIO circuit for illustration purposes. For example, a decoder 220 controls the shifting of the first GIO circuit 145. Similarly, a decoder 225 controls the shifting of the zeroth GIO circuit 180.

Should the first and zeroth GIO columns be included in a two-shift region, a data in signal from the first I/O circuit 145 couples to write driver 210-3 in the first redundant GIO column during a write operation to the first GIO column. Similarly, a data in signal from the zeroth I/O circuit 180 couples to write driver 210-4 in the second redundant GIO column during a write operation to the zeroth GIO column. An example switch matrix for each GIO circuit will now be discussed.

### Example Switch Matrices

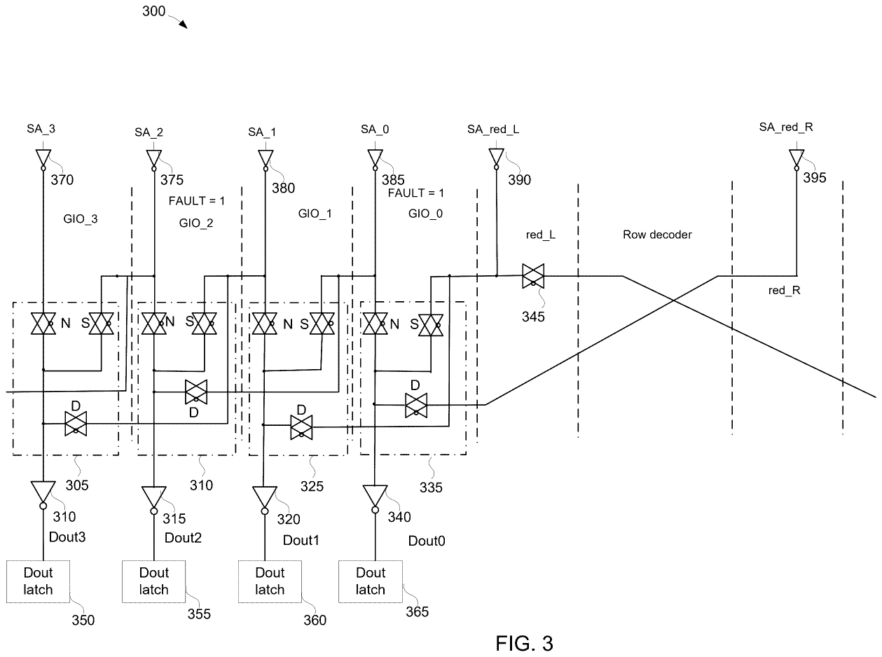

To perform the selection between a no-shift, a single-shift, and a double-shift within each GIO circuit, each GIO circuit includes a switch matrix. As used herein, a “switch matrix” is deemed to include a plurality of switches. The implementation of the switch matrix may be identical for both the read and write paths. An example portion 300 of a write path for a bank is shown in FIG. 3. Portion 300 includes a third GIO column (GIO_3), a second GIO column (GIO_2), a first GIO column (GIO_1), and a zeroth GIO column (GIO_0) for a first bank. Similarly, the portion 300 includes a left redundant GIO column (red_L) and a right redundant GIO column (red_R) that are separated by a row decoder for the first bank and for a second bank (not illustrated).

An output terminal of each GIO column may be formed by an output terminal of an inverter for inverting the GIO column's sense amplifier output signal. For example, a sense amplifier output signal (SA_3) for the third GIO column is inverted by an inverter 370. Similarly, an inverter 375 inverts a sense amplifier output signal SA_2 for the second GIO column whereas an inverter 380 inverts a sense amplifier output signal SA_1 for the first GIO column. In the same fashion, an inverter 385 inverts a sense amplifier output signal SA_0 for the zeroth GIO column. An inverter 390 inverts a sense amplifier output signal SA_red_L for the left redundant GIO column. Finally, an inverter 395 inverts aa sense amplifier output signal SA_red_R for the right redundant GIO column. However, it will be appreciated that the inverters 370 through 390 may be eliminated in alternative implementations.

A third GIO circuit includes a switch matrix 305, an inverter 310, and a data output latch 350. Similarly, a switch matrix 310, an inverter 315, and a data output latch 355 form part of a second GIO circuit. In the same fashion, a first GIO circuit includes a switch matrix 325, an inverter 320, and a data output latch 360. Finally, a zeroth GIO circuit includes a switch matrix 335, an inverter 340, and a data output latch 365.

Each switch matrix includes three switches such as formed by three corresponding transmission gates. A first transmission gate for each switch matrix is controlled by the GIO circuit's no-shift signal (N) and is thus also designated as a switch N. Similarly, a second transmission gate for each switch matrix is controlled by the GIO circuit's single-shift signal(S) and is thus also designated as a switch S. Finally, a third transmission gate for each switch matrix is controlled by the GIO circuit's double-shift signal (D) and is thus also designated as a switch D. The switch S couples between an output node for the default GIO's column and an input terminal for the GIO circuit's data output latch. For example, the transmission gate N in the switch matrix 305 for the third GIO circuit couples between an output terminal of the inverter 370 for the third GIO column and an input terminal for the data output latch 350.

Each switch S connects between an output node or terminal for the subsequent GIO column and an input terminal to the GIO circuit's data output latch. For example, the transmission gate S in the switch matrix 305 for the third GIO circuit connects between an output terminal of the inverter 375 for the second GIO column and an input terminal to the data output latch 350. As used herein, the term “connects” or “connected” with respect to a switch are defined as a direct electrical connection through the switch and excludes a coupling through additional switches. Each switch D connects between an output terminal for the next-to-subsequent GIO column and an input terminal for the GIO circuit's data output latch. For example, the transmission gate D for the switch matrix 305 of the third GIO circuit connects between an output terminal of the inverter 380 for the first GIO column and an input terminal to the data output latch 350. The third GIO column is in a no-shift region such that only the transmission gate N is open (conducting) in the switch matrix 305. The transmission gates S and D in the switch matrix 305 are thus closed (non-conducting).

The connection to the default GIO column for the switch N, connection to the subsequent GIO column for the switch S, and connection to the next-to-subsequent GIO column for the switch D is analogous for the remaining switch matrices. For example, the transmission gate N in the switch matrix 310 for the second GIO circuit connects between the output terminal of the inverter 375 for the second GIO column and an input terminal to the data output latch 355. Similarly, the transmission gate S in the switch matrix 310 connects between the output terminal of the inverter 380 for the first GIO column and the input terminal of the data output latch 355. Finally, the transmission gate D in the switch matrix 310 connects between an output terminal of the inverter 385 for the zeroth GIO column and the input terminal to the data output latch 355. The second GIO column is the initial faulty column in the first bank. Thus, the transmission gate S in the switch matrix 310 is open whereas the transmission gates D and N in the switch matrix 310 are closed.

Similarly, the transmission gate N in the switch matrix 325 for the first GIO circuit connects between the output terminal of the inverter 380 for the first GIO column and an input terminal to the data output latch 360. The transmission gate S in the switch matrix 325 connects between the output terminal of the inverter 385 for the zeroth GIO column and the input terminal of the data output latch 360. Finally, the transmission gate D in the switch matrix 325 connects between an output terminal of the inverter 390 for the left redundant GIO column and the input terminal of the data output latch 360. The first GIO column is in a one-shift region for the first bank. Thus, the transmission gate S in the switch matrix 325 is open whereas the transmission gates N and D are closed.

In addition, the transmission gate N in the switch matrix 335 for the zeroth GIO circuit connects between the output terminal of the inverter 385 for the zeroth GIO column and an input terminal of the data output latch 365. The transmission gate S in the switch matrix 335 connects between the output terminal of the inverter 390 for the left redundant GIO column and the input terminal of the data output latch 365. Finally, the transmission gate D in the switch matrix 335 for the zeroth GIO circuit connects between an output terminal of the inverter 395 for the right redundant GIO column and the input terminal of the data output latch 365. A transmission gate 345 functions as the transmission gate D for a switch matrix (not illustrated) for a zeroth column in the second bank. The zeroth GIO column is a second defective column in the first bank and is therefore in a two-shift region. The transmission gate D in the switch matrix 335 is therefore open whereas the transmission gates N and S in the switch matrix 335 are closed. As will be shown by the following discussion, the switching for the write path is analogous to the read path switching.

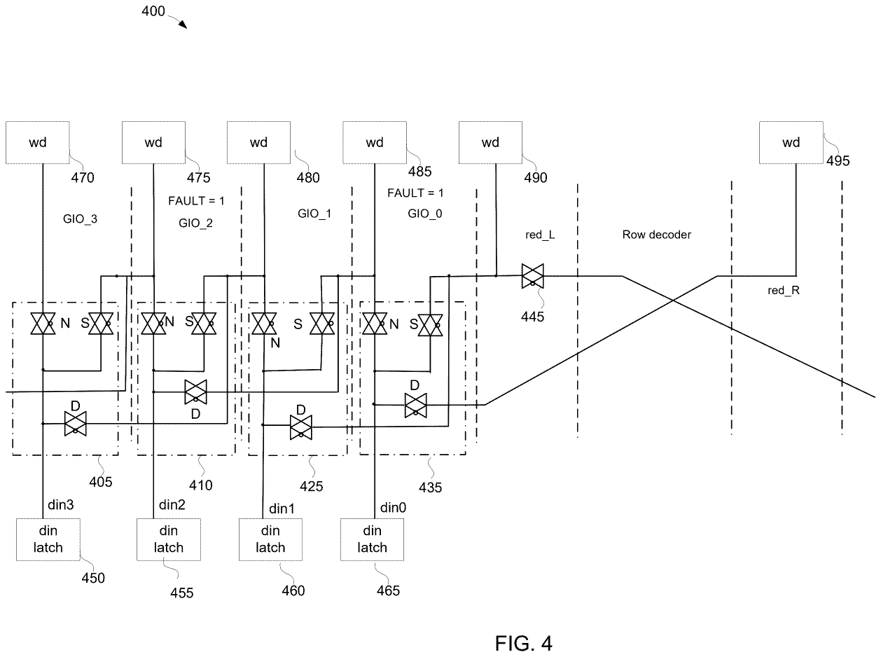

An example portion 400 of a write path for the first bank is shown in FIG. 4. Portion 400 includes the third GIO column (GIO_3), the second GIO column (GIO_2), the first GIO column (GIO_1), and the zeroth GIO column (GIO_0) for the first bank as discussed with respect to the read path portion 300 of FIG. 3. Similarly, the portion 400 includes the left redundant GIO column (red_L) and the right redundant GIO column (red_R) that are separated by a row decoder for the first bank and for a second bank (not illustrated) as also discussed with respect to the read path portion 300 of FIG. 3. The third GIO column includes a write driver 470. An input terminal to the write driver 470 thus functions as an input terminal to the third GIO column. Similarly, the second GIO column includes a write driver 475 having an input terminal that functions as the input terminal to the second GIO column. In the same fashion, the first GIO column includes a write driver 480 having an input terminal that functions as the input terminal to the first GIO column. In addition, the zeroth GIO column includes a write driver 485 having an input terminal that functions as the input terminal to the zeroth GIO column. Similarly, the left redundant GIO column includes a write driver 490 having an input terminal that functions as the input terminal to the left redundant GIO column. Finally, the right redundant GIO column includes a write driver 495 having an input terminal that functions as the input terminal to the right redundant GIO column.

A zeroth GIO circuit includes a switch matrix 435 and a data input latch (din latch) 465. A transmission gate N in the switch matrix 435 for the zeroth GIO circuit connects between the input terminal for the zeroth GIO column and an input terminal of the data input latch 465. A transmission gate S in the switch matrix 435 connects between the input terminal of the left redundant GIO column and the input terminal of the data input latch 465. Finally, a transmission gate D in the switch matrix 435 connects between an input terminal of the right redundant GIO column and the input terminal of the data input latch 465. A transmission gate 445 functions as the transmission gate D for a switch matrix (not illustrated) for a zeroth column in the second bank. The zeroth GIO column is a second defective column in the first bank such that the zeroth column is in a two-shift region. The transmission gate D in the switch matrix 435 is thus open whereas the transmission gates N and S in the switch matrix 435 are closed.

A first GIO circuit includes a switch matrix 425 and a data input latch (din latch) 460. A transmission gate N in the switch matrix 425 for the first GIO circuit connects between the input terminal for the first GIO column and an input terminal of the data input latch 460. A transmission gate S in the switch matrix 425 connects between the input terminal of the zeroth GIO column and the input terminal of the data input latch 460. Finally, a transmission gate D in the switch matrix 425 connects between an input terminal of the left redundant GIO column and the input terminal of the data input latch 460. The first GIO column is in a one-shift region as it is subsequent to the second GIO column that is defective. The transmission gate S in the switch matrix 425 is thus open whereas the transmission gates N and D in the switch matrix 425 are closed.

A second GIO circuit includes a switch matrix 410 and a data input latch (din latch) 455. A transmission gate N in the switch matrix 410 connects between the input terminal for the second GIO column and an input terminal of the data input latch 455. A transmission gate S in the switch matrix 410 connects between the input terminal of the first GIO column and the input terminal of the data input latch 455. Finally, a transmission gate D in the switch matrix 410 connects between an input terminal of the zeroth GIO column and the input terminal of the data input latch 455. The second GIO column is in a one-shift region as it the initial defective column. The transmission gate S in the switch matrix 410 is thus open whereas the transmission gates N and D in the switch matrix 410 are closed.

A third GIO circuit includes a switch matrix 405 and a data input latch (din latch) 450. A transmission gate N in the switch matrix 405 connects between the input terminal for the third GIO column and an input terminal of the data input latch 450. A transmission gate S in the switch matrix 405 connects between the input terminal of the second GIO column and the input terminal of the data input latch 450. Finally, a transmission gate D in the switch matrix 410 connects between an input terminal of the first GIO column and the input terminal of the data input latch 450. The third GIO column is in a no-shift region as it precedes the initial defective GIO column in the first bank. The transmission gate N in the switch matrix 410 is thus open whereas the transmission gates S and D in the switch matrix 410 are closed. An example decoder will now be discussed.

### Example Decoder

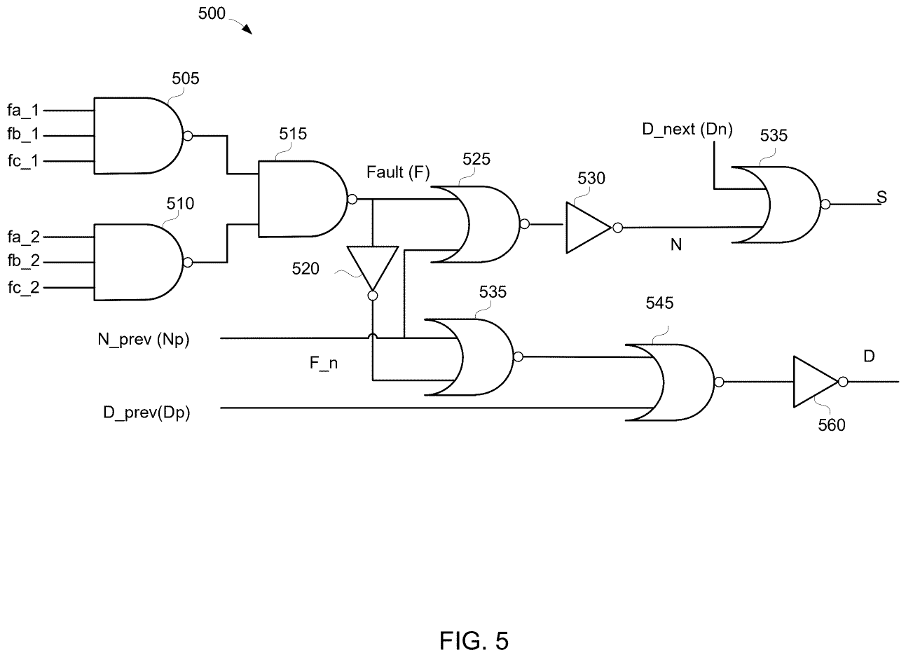

An example decoder 500 for an ith GIO circuit is shown in FIG. 5, where i is the index of the ith GIO column. One function of the decoder 500 is to determine whether the corresponding GIO column (in this case, the ith GIO column) is an initial defective GIO column or a second defective GIO column in the corresponding memory bank. As noted earlier, a test of a memory bank may be performed at manufacture to identify the addresses of the initial defective GIO column (if present) and of the second defective GIO column (if present). There is thus a set of pre-decoded address signals fa-1, fb-1, and fc-1 in one implementation that identify the first defective GIO column. These pre-decoded address signals are all true only for the redundancy decoder corresponding to the first defective GIO column. But at least one of them is false for all remaining redundancy decoders. For example, suppose that an ith GIO column is defective. The address signals fa-1, fb-1, and fc-1 would then all be true only for the ith GIO circuit, where i is the index of the defective GIO column. Similarly, there may be a set of pre-decoded address signals fa-2, fb-2, and fc-2 that identify the second defective GIO column. These pre-decoded address signals are all true only for the redundancy decoder for the GIO circuit having the same index as the second defective GIO column. But at least one of them is false for all remaining redundancy decoders.

In the decoder 500, a first NAND gate 505 functions to decode the pre-decoded address signals fa-1, fb-1, and fc-1. An output signal of first NAND gate 505 will be false only if the ith GIO column is the first defective GIO column and will be true otherwise. Similarly, a second NAND gate 510 functions to decode the pre-decoded address signals fa-2, fb-2, and fc-2. An output signal of second NAND gate 510 will be false only if the ith GIO column is the second defective GIO column and will be true otherwise.

A logic gate such as a NAND gate 515 NANDs the output signals from NAND gates 505 and 510 to produce a fault signal (F) that is asserted only if the ith GIO column is either the first or the second defective GIO column. Should the ith GIO column be the initial defective GIO column, the fault signal will be asserted but the no-shift signal N for the previous GIO column will also be asserted. A NOR gate 525 thus tests for this condition by NORing the no-shift signal (N_prev(Np)) from the previous GIO column with the fault signal. An output signal of the NOR gate 525 will thus be false only if the fault signal and the N_prev signal are both true, which indicates that the ith GIO column is the initial defective GIO column. An inverter 530 inverts the output signal from the NOR gate 525 to produce the no-shift signal (N) for the ith GIO column.

Should the fault signal be false and the N_prev signal be true, the no-shift signal N for the ith GIO column will be asserted by the inverter 530. But if the fault signal is asserted, the no-shift signal N is de-asserted by the inverter 530. A NOR gate 535 NORs the no-shift signal N with the double-shift signal (D_next(Dn))) from the subsequent GIO column to produce the single-shift signal(S) for the ith GIO column. The feedback of the D_next signal is advantageous because the subsequent GIO column may be the second defective GIO column. Should the single-shift signal S be asserted in such a case, an error may result in either a read or write operation to the subsequent GIO column. But the feedback of an asserted D_next signal causes the NOR gate 535 to de-assert the single-shift signal S.

If the ith GIO column is the second defective GIO column, the fault signal will be true and the N_prev signal from the previous GIO column will be false. To detect this condition, an inverter 520 inverts the fault signal to produce a complement fault signal (F_n) that is asserted when the fault signal is false and is de-asserted when the fault signal is true. A NOR gate 535 NORs the complement fault signal with the N_prev signal. An output signal from the NOR gate 535 will thus be asserted only if the ith GIO column is the second defective GIO column. A NOR gate 545 NORs the output signal form the NOR gate 535 with a double-shift signal (D_prev(Dp)) for the preceding GIO column. An output signal from the NOR gate 545 will be de-asserted in response to the output signal from the NOR gate 535 being true or from the D_prev signal being true. An inverter 560 inverts the output signal from the NOR gate 545 to produce the double-shift signal (D) for the ith GIO column. It may thus be seen that the D signal will be asserted whenever the D signal from the preceding GIO column is asserted or in response to the ith GIO column being the second defective GIO column. It will be appreciated that the logic gates shown for decoder 500 are merely exemplary and that other combinations of logic gates may provide an equivalent decoding.

Note that the single and double GIO column shifting by the switch matrices disclosed herein does not affect the column multiplexing in the local data paths. In other words, the column redundancy disclosed herein is independent of the column multiplexing, i.e., whether the column multiplexing is MUX2, MUX4, and so on. The column redundancy disclosed herein may thus be readily implemented in any suitable memory bank, regardless of the column multiplexing magnitude.

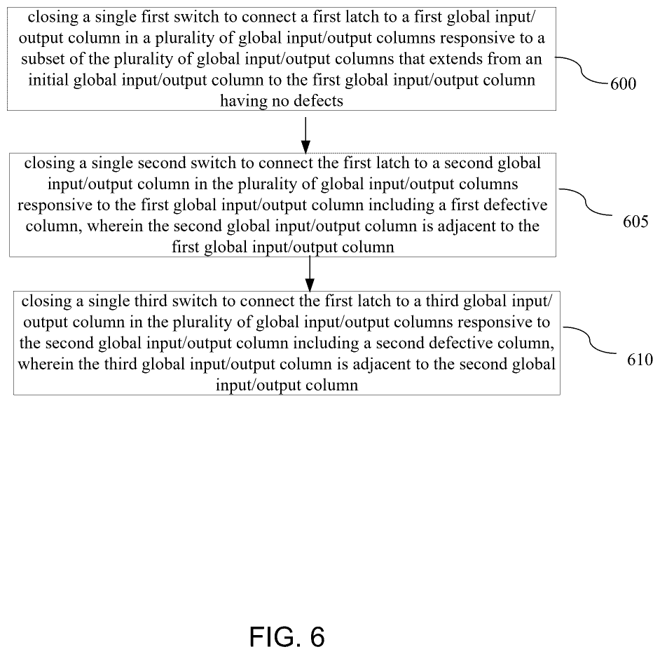

A double redundancy shift method of operation for a memory will now be discussed with regard to the flowchart of FIG. 6. The method includes an act 600 of closing a single first switch to connect a first latch to a first global input/output column in a plurality of global input/output columns responsive to a subset of the plurality of global input/output columns that extends from an initial global input/output column to the first global input/output column having no defects. The opening of the N transmission gate in the switch matrix 305 or in the switch matrix 405 is an example of act 600. The method also includes an act 605 of closing a single second switch to connect the first latch to a second global input/output column in the plurality of global input/output columns responsive to the first global input/output column including a first defective column, wherein the second global input/output column is adjacent to the first global input/output column. The opening of the S transmission gate in the switch matrix 305 or in the switch matrix 405 is an example of act 605. Finally, the method includes an act 610 of closing a single third switch to connect the first latch to a third global input/output column in the plurality of global input/output columns responsive to the second global input/output column including a second defective column, wherein the third global input/output column is adjacent to the second global input/output column. The opening of the transmission gate D in the switch matrix 305 or in the switch matrix 405 is an example of act 610.

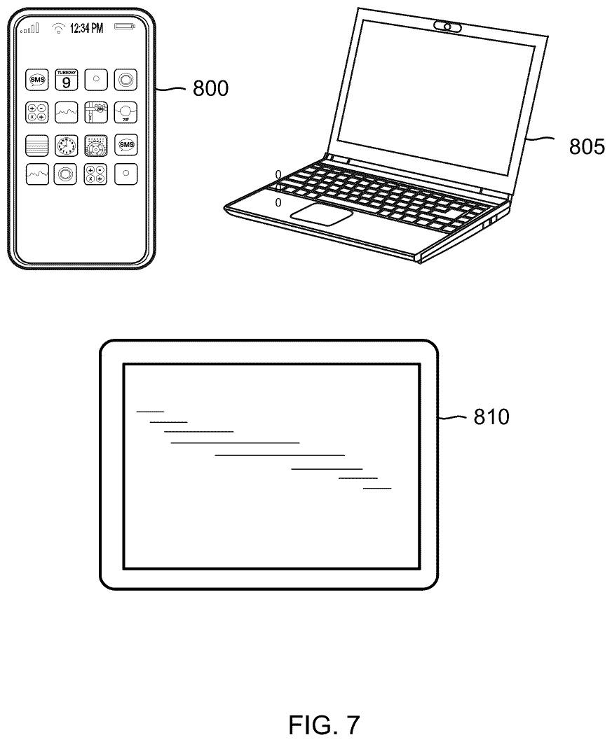

A memory as disclosed herein may be incorporated into a wide variety of electronic systems. For example, as shown in FIG. 7, a cell phone 700, a laptop 705, and a tablet PC 710 may all include a memory having a double redundancy shift in accordance with the disclosure. Other exemplary electronic systems such as a music player, a video player, a communication device, and a personal computer may also be configured with memories constructed in accordance with the disclosure.

The disclosure will now be summarized by the following example clauses:

Clause 1. A memory, comprising:
a first global input/output column of bitcells;
a second global input/output column of bitcells;
a third global input/output column of bitcells, wherein the first global input/output column, the second global input/output column, and the third global input/output column are arranged in a consecutive order within a first bank;
a first data output latch; and
a switch matrix including a first switch connected between an output terminal of the first global input/output column and an input terminal of the first data output latch, a second switch connected between an output terminal of the second global input/output column and the input terminal of the first data output latch, and a third switch coupled between an output terminal of the third global input/output column and the input terminal of the first data output latch.

Clause 2. The memory of clause 1, wherein the switch matrix includes no additional switches.

Clause 3. The memory of any of clauses 1-2, further comprising:
a first decoder configured to close the first switch, open the second switch, and open the third switch responsive to the first bank having no defective global input/output column from an initial global input/output column to the first global input/output column.

Clause 4. The memory of clause 3, wherein the first decoder is further configured to open the first switch, close the second switch, and close the third switch responsive to the first global input/output column being an initial defective global input/output column in the first bank.

Clause 5. The memory of any of clauses 3-4, wherein the first decoder is further configured to open the first switch, open the second switch, and close the third switch responsive to the second global input/output column being a second defective global input/output column in the first bank.

Clause 6. The memory of any of clauses 1-5, wherein the memory further comprises:
a first redundant global input/output column; and
a second redundant global input/output column.

Clause 7. The memory of clause 6, further comprising:
a second bank; and
a row decoder disposed between the first bank and the second bank, wherein the first redundant global input/output column is disposed between the first bank and the row decoder and the second redundant global input/output column is disposed between the row decoder and the second bank.

Clause 8. The memory of any of clauses 1-7, wherein the first switch, the second switch, and the third switch each comprises a transmission gate.

Clause 9. The memory of any of clauses 1-8, wherein the memory is included in a cellular telephone.

Clause 10. The memory of any of clauses 1-9, wherein the memory is a static random-access memory (SRAM).

Clause 11. A memory, comprising:
a first global input/output column of bitcells;
a second global input/output column of bitcells;
a third global input/output column of bitcells, wherein the first global input/output column, the second global input/output column, and the third global input/output column are arranged in a consecutive order;
a first data input latch; and
a first switch matrix having a first switch connected between an output terminal of the first data input latch and an input terminal of the first global input/output column, a second switch connected between the output terminal of the first data input latch and an input terminal of the second global input/output column, and a third switch coupled between the output terminal of the first data input latch and an input terminal of the third global input/output column.

Clause 12. The memory of clause 11, wherein the first global input/output column, the second global input/output column, and the third global input/output column are included in a first bank, the memory further comprising:
a first decoder configured to control the first switch matrix responsive to whether the first global input/output column is in a no-shift region of the first bank, a one-shift region of the first bank, or a two-shift region of the first bank.

Clause 13. The memory of clause 12, wherein the first decoder is further configured to decode an address of the first global input/output column to determine whether the first global input/output column is in the no-shift region, the one-shift region, or the two-shift region.

Clause 14. The memory of any of clauses 12-13, wherein the memory further comprises:
a first redundant global input/output column; and
a second redundant global input/output column.

Clause 15. The memory of clause 14, further comprising:
a second bank; and
a row decoder disposed between the first bank and the second bank, wherein the first redundant global input/output column is disposed between the first bank and the row decoder and the second redundant global input/output column is disposed between the row decoder and the second bank.

Clause 16. The memory of any of clauses 11-15, wherein the first switch matrix includes no additional switches.

Clause 17. A method of column redundancy, comprising:
closing a single first switch to connect a first latch to a first global input/output column in a plurality of global input/output columns responsive to a subset of the plurality of global input/output columns that extends from an initial global input/output column to the first global input/output column having no defects;
closing a single second switch to connect the first latch to a second global input/output column in the plurality of global input/output columns responsive to the first global input/output column including a first defective column, wherein the second global input/output column is adjacent to the first global input/output column; and
closing a single third switch to connect the first latch to a third global input/output column in the plurality of global input/output columns responsive to the second global input/output column including a second defective column, wherein the third global input/output column is adjacent to the second global input/output column.

Clause 18. The method of clause 17, further comprising: decoding a first address to determine whether the first global input/output column includes the first defective column.

Clause 19. The method of any of clauses 17-18, further comprising:
coupling a final latch to a final global/input column in the plurality of global input/output columns responsive to the plurality of global input/output columns having no defects.

Clause 20. The method of clause 19, further comprising:
coupling the final latch to a first redundant global input/output column responsive to the plurality of global input/output columns including the first defective column and not including the second defective column.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory, comprising:
a first global input/output column of bitcells;
a second global input/output column of bitcells;
a third global input/output column of bitcells, wherein the first global input/output column, the second global input/output column, and the third global input/output column are arranged in a consecutive order within a first bank;
a first data output latch; and
a switch matrix including a first switch connected between an output terminal of the first global input/output column and an input terminal of the first data output latch, a second switch connected between an output terminal of the second global input/output column and the input terminal of the first data output latch, and a third switch coupled between an output terminal of the third global input/output column and the input terminal of the first data output latch.

2. The memory of claim 1, wherein the switch matrix includes no additional switches.

3. The memory of claim 1, further comprising:
a first decoder configured to close the first switch, open the second switch, and open the third switch responsive to the first bank having no defective global input/output column from an initial global input/output column to the first global input/output column.

4. The memory of claim 3, wherein the first decoder is further configured to open the first switch, close the second switch, and close the third switch responsive to the first global input/output column being an initial defective global input/output column in the first bank.

5. The memory of claim 3, wherein the first decoder is further configured to open the first switch, open the second switch, and close the third switch responsive to the second global input/output column being a second defective global input/output column in the first bank.

6. The memory of claim 1, wherein the memory further comprises:
a first redundant global input/output column; and
a second redundant global input/output column.

7. The memory of claim 6, further comprising:
a second bank; and
a row decoder disposed between the first bank and the second bank, wherein the first redundant global input/output column is disposed between the first bank and the row decoder and the second redundant global input/output column is disposed between the row decoder and the second bank.

8. The memory of claim 1, wherein the first switch, the second switch, and the third switch each comprises a transmission gate.

9. The memory of claim 1, wherein the memory is included in a cellular telephone.

10. The memory of claim 1, wherein the memory is a static random access memory (SRAM).

11. A memory, comprising:
a first global input/output column of bitcells;
a second global input/output column of bitcells;
a third global input/output column of bitcells, wherein the first global input/output column, the second global input/output column, and the third global input/output column are arranged in a consecutive order;
a first data input latch; and
a first switch matrix having a first switch connected between an output terminal of the first data input latch and an input terminal of the first global input/output column, a second switch connected between the output terminal of the first data input latch and an input terminal of the second global input/output column, and a third switch coupled between the output terminal of the first data input latch and an input terminal of the third global input/output column.

12. The memory of claim 11, wherein the first global input/output column, the second global input/output column, and the third global input/output column are included in a first bank, the memory further comprising:
a first decoder configured to control the first switch matrix responsive to whether the first global input/output column is in a no-shift region of the first bank, a one-shift region of the first bank, or a two-shift region of the first bank.

13. The memory of claim 12, wherein the first decoder is further configured to decode an address of the first global input/output column to determine whether the first global input/output column is in the no-shift region, the one-shift region, or the two-shift region.

14. The memory of claim 12, wherein the memory further comprises:
a first redundant global input/output column; and
a second redundant global input/output column.

15. The memory of claim 14, further comprising:
a second bank; and
a row decoder disposed between the first bank and the second bank, wherein the first redundant global input/output column is disposed between the first bank and the row decoder and the second redundant global input/output column is disposed between the row decoder and the second bank.

16. The memory of claim 11, wherein the first switch matrix includes no additional switches.

17. A method of column redundancy, comprising:
closing a single first switch to connect a first latch to a first global input/output column in a plurality of global input/output columns responsive to a subset of the plurality of global input/output columns that extends from an initial global input/output column to the first global input/output column having no defects;
closing a single second switch to connect the first latch to a second global input/output column in the plurality of global input/output columns responsive to the first global input/output column including a first defective column, wherein the second global input/output column is adjacent to the first global input/output column; and
closing a single third switch to connect the first latch to a third global input/output column in the plurality of global input/output columns responsive to the second global input/output column including a second defective column, wherein the third global input/output column is adjacent to the second global input/output column.

18. The method of claim 17, further comprising:
decoding a first address to determine whether the first global input/output column includes the first defective column.

19. The method of claim 17, further comprising:
coupling a final latch to a final global/input column in the plurality of global input/output columns responsive to the plurality of global input/output columns having no defects.

20. The method of claim 19, further comprising:
coupling the final latch to a first redundant global input/output column responsive to the plurality of global input/output columns including the first defective column and not including the second defective column.
